(19) United States
(12) Patent Application Publication
(10) Pub. No.: US 2018/0197722 A1
(43) Pub. Date: Jul. 12, 2018

(54) CATHODE WITH IMPROVED RF POWER EFFICIENCY FOR SEMICONDUCTOR PROCESSING EQUIPMENT WITH RF PLASMA

(71) Applicant: Lam Research Corporation, Fremont, CA (US)

(72) Inventor: Maolin LONG, Santa Clara, CA (US)

(21) Appl. No.: 15/403,039

(22) Filed: Jan. 10, 2017

(51) Int. Cl. H01J 37/32; H01L 21/683; H01L 21/67

(52) U.S. Cl. CPC H01J 37/32559; H01L 21/6833; H01L 21/67069; H01J 37/32834; H01J 2237/334; H01J 37/32137; H01J 37/32541; H01J 37/32697; H01J 37/32715; H01J 37/3211

(57) ABSTRACT

A cathode assembly for use in a plasma processing chamber is provided. A metal bowl that is grounded is provided. An insulator of a sealed porous or sealed honeycomb dielectric ceramic with an equivalent dielectric constant k<7 is on top of the metal bowl. An electrostatic chuck (ESC) is on top of the insulator, wherein the insulator electrically insulates the metal bowl from the ESC.

### BACKGROUND

The disclosure relates to a method and apparatus for plasma processing a substrate. More specifically, the disclosure relates to a method and apparatus for providing a cathode with an electrostatic chuck.

In a plasma processing chamber a cathode assembly may insulate the ESC (electrostatic chuck), whose baseplate is RF hot, from a grounded bowl by an insulator.

### SUMMARY

To achieve the foregoing and in accordance with the purpose of the present disclosure, a cathode assembly for use in a plasma processing chamber is provided. A metal bowl that is grounded is provided. An insulator of a sealed porous or sealed honeycomb dielectric ceramic with an equivalent dielectric constant k<7 is on top of the metal bowl. An electrostatic chuck (ESC) is on top of the insulator, wherein the insulator electrically insulates the metal bowl from the ESC.

In another manifestation, an apparatus, for plasma processing a substrate is provided. A plasma processing chamber is provided. An electrode supports the substrate within the plasma processing chamber. An RF power source is provided. A power connection is electrically connected between the RF power source and the electrode. A grounded metal bowl is below the electrode. An insulator of a sealed porous or sealed honeycomb dielectric ceramic with an equivalent dielectric constant k<7 is on top of the metal bowl between the electrode and the grounded metal bowl to insulate the grounded metal bowl from the electrode. A gas source flows a process gas into the plasma processing chamber. A pump exhausts gas from the plasma processing chamber.

These and other features of the present invention will be described in more details below in the detailed description of the invention and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic cross-sectional view of a cathode assembly used in an embodiment.

FIG. 2 is a perspective view of an insulator used in an embodiment.

FIG. 3 is a schematic illustration of a plasma processing system used in an embodiment.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

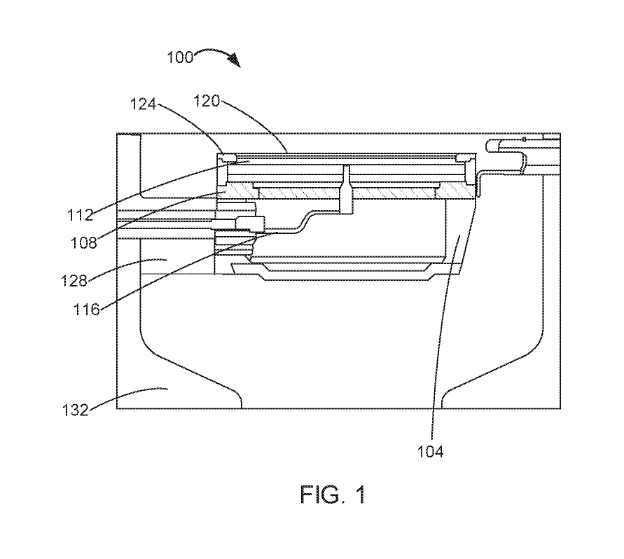

FIG. 1 is a schematic cross-sectional view of a cathode assembly 100 that may be used in an embodiment. A grounded electrically conductive metal bowl 104 is provided. An insulator 108, which is shown as shaded, is supported by the grounded electrically conductive metal bowl 104. An electrostatic chuck (ESC) 112 is placed over the insulator 108, so that the insulator 108 provides electrical insulation between the ESC 112 and the grounded electrically conductive metal bowl 104. A power connection 116 is electrically connected to the electrostatic chuck 112. The power connection 116 is electrically insulated from the conductive metal bowl 104. In this embodiment, a substrate 120, such as a wafer, is placed on the ESC 112. An edge ring 124 surrounds the substrate 120. In this embodiment, a side mount 128 passes through a side of a plasma processing chamber 132, where the side mount 128 supports the grounded electrically conductive metal bowl 104 and where the power connection 116 enters the plasma processing chamber 132.

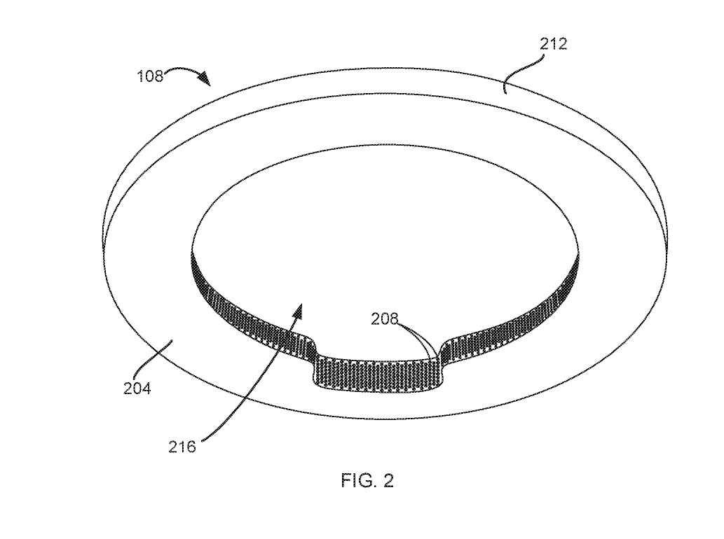

FIG. 2 is an enlarged and perspective view of the insulator 108 in this embodiment. The insulator 108 is in a ring shape, which forms an aperture 216 to provide a space for connections, such as the power connection 116 to pass between the grounded conductive metal bowl 104 and the ESC 112, shown in FIG. 1. The insulator 108 has a ceramic body 204, which in this embodiment is aluminum oxide. A plurality of apertures 208 are formed in the ceramic body 204, so that the ceramic body 204 has a honeycomb shape. In this embodiment, an outer circumference wall 212 of the insulator 108 is smooth, since the apertures 208 do not pass completely through the ceramic body 204, so that the outer circumference wall 212 forms a vacuum seal for all of the apertures 208. The apertures 208 must be sealed at either the ends or in between to provide a sealed honeycomb dielectric. The sealing of the apertures prevents gases from flowing through the insulator 108 through the apertures 208. The honeycomb shape provides a total insulator volume to an aperture volume ratio typically no higher than 3:1, where the total insulator volume is the total volume of the ceramic and honeycomb apertures, meaning that the air volume of the honeycomb is typically more than ⅓ of the total volume of the insulator ring's envelope. The combination of the ceramic and the sealed apertures provide an equivalent dielectric constant of k<7, where the equivalent dielectric constant is the dielectric constant value of the insulating ring of a material of the k value, if the insulating ring was solid without apertures and had the same envelope dimensions as the honeycomb insulator.

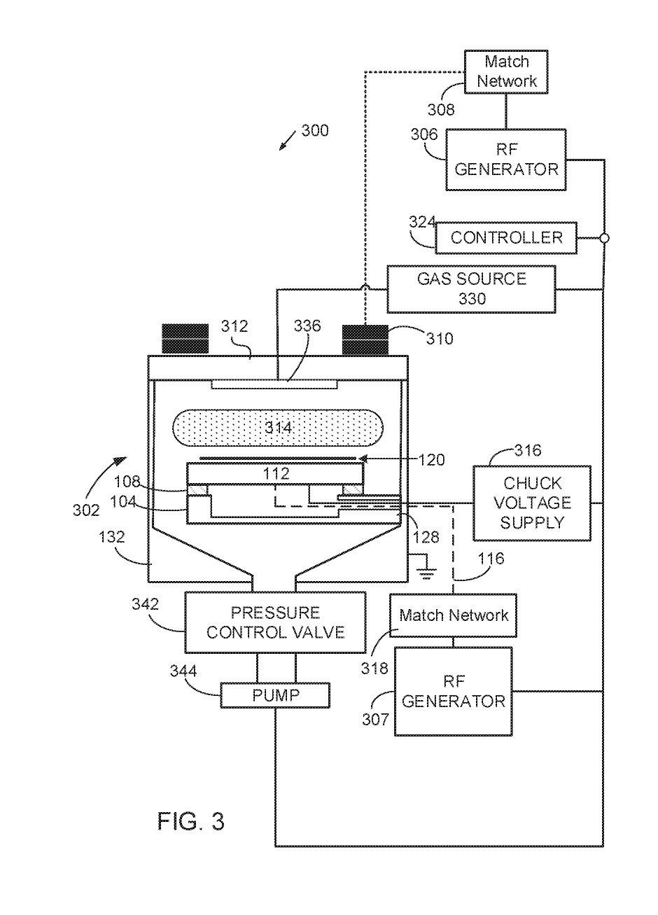

FIG. 3 schematically illustrates an example of a plasma processing system 300 which may use the above embodiment. The plasma processing system 300 includes a plasma reactor 302 having a plasma processing chamber 132. RF generators 306 and 307, tuned by a match networks 308 and 318 respectively, supply RF power to a TCP coil 310 located near a power window 312 to create a plasma 314 in the plasma processing chamber 132 with inductively coupled RF power, and RF power to the cathode to control mainly the ion energy while also helping create the plasma with capacitively coupled RF power, respectively. The TCP coil (upper power source) 310 may be configured to produce a uniform diffusion profile within the plasma processing chamber 132. For example, the TCP coil 310 may be configured to generate a toroidal power distribution in the plasma 314. The dielectric window 312 is provided to make the vacuum seal and separate the TCP coil 310 from the plasma processing chamber 132 while allowing energy to pass from the TCP coil 310 to the plasma 314. The bias RF generator 307 tuned by a match network 318 provides RF bias power to an ESC 112 through a power connection 116 to control the ion energy moving towards the top surface of the substrate 120 which is supported and held by the ESC 112. A controller 324 controls all the parameters for wafer processing, including TCP RF power, bias RF power, chamber pressure, gas flow rates, chucking voltage, etc., to mention a few

The RF generators 306 and 307 may be configured to operate at specific radio frequencies such as, 13.56 MHz, 27 MHz, 2 MHz, 400 kHz, etc., or combinations thereof. RF generators 306 and 307 may be appropriately sized to supply a range of powers in order to achieve desired process performance. For example, in one embodiment, the TCP RF generator 306 may supply the power in a range of 50 W to 5000 W, and the bias RF generator 307 may supply a power in the range of 5 W to 3000 W to create a bias RF voltage of 20V to 2000 V. In addition, the TCP coil 310 and/or the ESC 112 may be comprised of two or more sub-coils or sub-electrodes, which may be powered by a single power supply or powered by multiple power supplies.

As shown in FIG. 3, the plasma processing system 300 further includes a gas source/gas supply mechanism 330. The gas source/gas supply mechanism 330 provides gases to a gas feed 336 in the form of a gas injector or a shower head. The process gases and byproducts are removed from the plasma processing chamber 132 via a pressure control valve 342 and a pump 344, which also serve to maintain a particular pressure within the plasma processing chamber 132. The gas source/gas supply mechanism 330 is controlled by the controller 324.

An insulator ring 108 is supported on the grounded electrically conductive metal bowl 104 and supports the ESC 112 and electrically insulates the ESC 112 from the grounded electrically conductive metal bowl 104. A side mount 128 passes into the plasma processing chamber 132, where the side mount 128 supports the grounded electrically conductive metal bowl 104 and where the bias RF power connection 116 enters the bowl 104. A Kiyo series plasma etch chamber for conductor etch applications by Lam Research Corp. of Fremont, Calif., may be used to practice an embodiment.

In operation, the substrate 120 is placed on the ESC 112. Gas(es) is flowed from the gas source 330 into the plasma processing chamber 132. RF power is provided from the RF generator 306 to the TCP coil 310, which strikes the gas into a plasma. RF power is provided from the bias RF generator 307 through the match network 318 and the power connection 116, to the ESC 112, which controls the ion energy.

Solid aluminum oxide ceramic has a dielectric constant k of at least 9. Due to the relatively high dielectric constant of a solid aluminum oxide ceramic insulator ring, the stray capacitance between the ESC and the bowl when using a solid aluminum oxide ceramic insulator ring is about 300 pF in Kiyo. To improve RF power efficiency of the cathode or RF bias system, this stray capacitance needs to be minimized by decreasing the dielectric constant of the insulator.

In other embodiments, the cathode assembly may be used in a plasma processing system using a capacitively coupled power (CCP) source, like the Lam Flex series product for dielectric etch applications. RF power efficiency improvement for CCP source or RF bias with the innovation in this disclosure for plasma processing equipment saves energy in two ways. First, with higher RF power efficiency, plasma with the same density and/or ion energy can be produced, while using less RF power. Second, higher RF power efficiency means less power loss to the rest of the RF system, which thus produces less heat that takes less energy to cool down the system.

In other embodiments, other sealed honeycomb systems may be used. Apertures may extend through the body and be sealed at both ends. The sealed apertures may extend horizontally, vertically, or at other angles. The main criteria are to provide an insulator that is mechanically strong enough to support the ESC during the wafer processing and provide a seal against fluid leakage and provide an equivalent k less than 7. In addition, a ceramic body does not cause smoke contamination. More generally a sealed honeycomb system would have a plurality of substantially parallel apertures passing through most of the ceramic body, where each aperture has at least one seal. Preferably, the apertures have only one seal. More preferably, the insulator has an equivalent k less than 5. Most preferably, the insulator has an equivalent k less than 3. Various methods may be used to form the ceramic body with the honeycomb structure. The ceramic body may be molded with apertures. In another embodiment, the ceramic body is molded without apertures and then the apertures are machined into the ceramic body.

A dielectric layer may form a top layer of the ESC. Heating, cooling, and other elements may be placed in the ESC, which may provide temperature control.

In other embodiments, the insulator is a sealed porous ceramic insulator. A sealed porous ceramic insulator is a ceramic body which is porous. However, the pores must be configured so that fluid is not able to pass through the ceramic body. The sealed porous shape provides a total insulator volume to pore volume ratio of at least 3:1, where the total insulator volume is the total volume of the ceramic and pores. The combination of the ceramic and the sealed pores provide an equivalent dielectric constant of k<7. More preferably, the insulator has an equivalent k less than 5. Most preferably, the insulator has an equivalent k less than 3.

The above embodiment used a ceramic of aluminum oxide, also called alumina. Preferably, the ceramic is high purity alumina. In other embodiments, other ceramics such as AlN, Yttria, etc., may be used.

While this invention has been described in terms of several preferred embodiments, there are alterations, modifications, permutations, and various substitute equivalents, which fall within the scope of this invention. It should also be noted that there are many alternative ways of implementing the methods and apparatuses of the present invention. It is therefore intended that the following appended claims be interpreted as including all such alterations, modifications, permutations, and various substitute equivalents as fall within the true spirit and scope of the present invention.

What is claimed is:

1. A cathode assembly for use in a plasma processing chamber, comprising:
a metal bowl that is grounded;
a insulator of a sealed porous or sealed honeycomb dielectric ceramic on top of the metal bowl with an equivalent dielectric constant k<7; and
an electrostatic chuck (ESC) on top of the insulator, wherein the insulator electrically insulates the metal bowl from the ESC.

2. The cathode assembly, as recited in claim 1, further comprising a power connection electrically connected to the ESC.

3. The cathode assembly, as recited in claim 2, wherein the power connection is electrically connected to a RF power source.

4. The cathode assembly, as recited in claim 3, wherein the insulator is formed from a dielectric ceramic comprising at least one of aluminum oxide, AlN, or Yttria.

5. The cathode assembly, as recited in claim 4, wherein the insulator is sealed honeycomb dielectric ceramic.

6. The cathode assembly, as recited in claim 5, wherein the insulator has an equivalent dielectric constant k<5.

7. The cathode assembly, as recited in claim 5, wherein the insulator has an equivalent dielectric constant k<3.

8. The cathode assembly, as recited in claim 7, wherein the insulator is in a ring shape.

9. The cathode assembly, as recited in claim 1, wherein the insulator is formed from a dielectric ceramic comprising at least one of aluminum oxide, AlN, or Yttria.

10. The cathode assembly, as recited in claim 1, wherein the insulator is sealed honeycomb dielectric ceramic.

11. The cathode assembly, as recited in claim 1, wherein the insulator has an equivalent dielectric constant k<5.

12. The cathode assembly, as recited in claim 1, wherein the insulator has an equivalent dielectric constant k<3.

13. The cathode assembly, as recited in claim 1, wherein the insulator is in a ring shape.

14. An apparatus, for plasma processing a substrate, comprising:
a plasma processing chamber;
an electrode, which supports the substrate within the plasma processing chamber;
an RF power source;
a power connection electrically connected between the RF power source and the electrode;
a grounded metal bowl below the electrode;
an insulator of a sealed porous or sealed honeycomb dielectric ceramic on top of the metal bowl with an equivalent dielectric constant k<7 between the electrode and the grounded metal bowl to insulate the grounded metal bowl from the electrode;
a gas source for flowing a process gas into the plasma processing chamber; and
a pump for exhausting gas from the plasma processing chamber.

15. The apparatus, as recited in claim 14, wherein the insulator is formed from a dielectric ceramic comprising at least one of aluminum oxide, AlN, or Yttria.

16. The apparatus, as recited in claim 14, wherein the insulator has an equivalent dielectric constant k<5.

17. The apparatus, as recited in claim 14, wherein the insulator has an equivalent dielectric constant k<3.

18. The apparatus, as recited in claim 14, wherein the insulator is in a ring shape.
